(19) United States
(12) Patent Application Publication
(10) Pub. No.: US 2021/0211117 A1
(43) Pub. Date: Jul. 8, 2021

(54) RECEIVING FILTER CIRCUIT AND DUPLEXER HAVING THE SAME

(71) Applicant: WISOL CO., LTD., Osan-si (KR)

(72) Inventors: Bong Gi KIM, Osan-si (KR); Kensei UEHARA, Osan-si (KR); Ju Hyeong LEE, Osan-si (KR); Takahiro SATO, Osan-si (KR)

(21) Appl. No.: 17/142,497

(22) Filed: Jan. 6, 2021

(30) Foreign Application Priority Data
Jan. 6, 2020 (KR) 10-2020-0001540

(51) Int. Cl. H03H 9/64; H03H 9/02

(52) U.S. Cl. CPC H03H 9/6489; H03H 9/02574; H03H 9/02968

(57) ABSTRACT

A receiving filter circuit includes: a double mode surface acoustic wave (DMS) filter placed on a piezoelectric substrate and having a first reflector and a plurality of comb-shaped electrodes located adjacent to the first reflector; and a surface acoustic wave (SAW) resonator placed on the piezoelectric substrate in such a manner as to be laid on at least a portion of a transmission path of a surface acoustic wave generated from the DMS filter and having a second reflector located on a position with a distance of zero from the first reflector and a plurality of comb-shaped electrodes located adjacent to the second reflector.

### CROSS-REFERENCE TO RELATED APPLICATION

The present application claims the benefit of Korean Patent Application No. 10-2020-0001540 filed in the Korean Intellectual Property Office on Jan. 6, 2020, the entire content of which is incorporated herein by reference.

### BACKGROUND OF THE INVENTION

### 1. Field of the Invention

The present invention relates to a receiving filter circuit having a surface acoustic wave (SAW) resonator and a duplexer having the same.

### 2. Description of Related Art

Generally, many of receiving filter circuits and duplexers used particularly for mobile communication are configured to have a double mode SAW (DMS) filter and an SAW resonator located on a piezoelectric substrate.

In the case where the DMS filter and the SAW resonator are serially located adjacent to each other so as to miniaturize the receiving filter circuit (or duplexer) in conventional practices, however, the attenuation and/or isolation characteristics of the receiving filter circuit (or duplexer) may be deteriorated badly due to the spurious signals generated by the acoustic coupling between the DMS filter and the SAW resonator.

### SUMMARY OF THE INVENTION

Accordingly, the present invention has been made in view of the above-mentioned problems occurring in the related art, and it is an object of the present invention to provide a receiving filter circuit and a duplexer using the same that are capable of achieving an improvement in their performance.

It is another object of the present invention to provide a receiving filter circuit and a duplexer using the same that are capable of being miniaturized in size.

It is yet another object of the present invention to provide a receiving filter circuit and a duplexer using the same that are capable of achieving an improvement in the isolation and/or attenuation characteristics thereof.

To accomplish the above-mentioned objects, according to one aspect of the present invention, there is provided a receiving filter circuit including: a double mode surface acoustic wave (DMS) filter placed on a piezoelectric substrate and having a first reflector and a plurality of comb-shaped electrodes located adjacent to the first reflector; and a surface acoustic wave (SAW) resonator placed on the piezoelectric substrate in such a manner as to be laid on at least a portion of a transmission path of a surface acoustic wave generated from the DMS filter and having a second reflector located on a position with a distance of zero from the first reflector and a plurality of comb-shaped electrodes located adjacent to the second reflector.

To accomplish the above-mentioned objects, according to another aspect of the present invention, there is provided a duplexer including a receiving filter circuit including: a double mode surface acoustic wave (DMS) filter placed on a piezoelectric substrate and having a first reflector and a plurality of comb-shaped electrodes located adjacent to the first reflector; and a surface acoustic wave (SAW) resonator placed on the piezoelectric substrate in such a manner as to be laid on at least a portion of a transmission path of a surface acoustic wave generated from the DMS filter and having a second reflector located on a position with a distance of zero from the first reflector and a plurality of comb-shaped electrodes located adjacent to the second reflector.

According to the present invention, desirably, the first reflector includes a first electrode portion in which one electrode finger has a first unit section (d₁), the second reflector includes a second electrode portion in which one electrode finger has a second unit section (d₂), the first reflector or the second reflector including a third electrode portion in which one electrode finger has a third unit section (d₃) in such a manner as to be located between the first electrode portion and the second electrode portion, and the second unit section (d₂) and the third unit section (d₃) are set to satisfy a relation equation 1.04≥d₃/d₂≥1.03.

According to the present invention, desirably, the first reflector and the second reflector are located in such a manner as to allow an end portion of a unit section of the outermost electrode finger of the first reflector to correspond to an end portion of a unit section of the outermost electrode finger of the second reflector.

According to the present invention, desirably, the first unit section (d₁) is greater than the third unit section (d₃).

According to the present invention, desirably, the first electrode portion serves to reflect a surface acoustic wave emitted from the plurality of comb-shaped electrodes of the DMS filter towards the DMS filter, the second electrode portion serves to reflect a surface acoustic wave emitted from the plurality of comb-shaped electrodes of the SAW resonator towards the SAW resonator, and the third electrode portion serves to offset the surface acoustic wave emitted from the plurality of comb-shaped electrodes of the DMS filter with the surface acoustic wave emitted from the plurality of comb-shaped electrodes of the SAW resonator.

According to the present invention, desirably, the SAW resonator is a serial arm SAW resonator or parallel arm SAW resonator.

### BRIEF DESCRIPTION OF THE DRAWINGS

The above and other objects, features and advantages of the present invention will be apparent from the following detailed description of the embodiments of the invention in conjunction with the accompanying drawings, in which:

FIG. 1 is a schematic diagram showing a portion of a configuration of an SAW device (duplexer) having an SAW resonator in a conventional practice;

FIGS. 2A and 2B are graphs showing the isolation and attenuation characteristics of the SAW device of FIG. 1;

FIGS. 3A and 3B are schematic diagrams showing the comparison between the present invention and the conventional practice;

FIG. 4A is a top view showing a portion of a configuration of an SAW device (duplexer) according to an embodiment of the present invention;

FIG. 4B is a schematic circuit diagram showing a portion of the configuration of the SAW device of FIG. 4A;

FIG. 5 shows a position relation between a DMS filter of FIGS. 4A and 4B and a first parallel arm SAW resonator;

FIG. 6 shows a position relation between a DMS filter of FIG. 1 and the SAW resonator;

FIGS. 7A and 7B are graphs showing the comparison of the isolation and attenuation characteristics between the SAW device of FIGS. 4A and 4B and the SAW device of FIG. 1;

FIG. 8 is a schematic diagram showing examples of unit section lengths of electrode fingers of a DMS filter, a first reflector, a second reflector, and the SAW resonator of FIGS. 4A and 4B;

FIGS. 9A and 9B are graphs showing the isolation and/or attenuation characteristics of the SAW device of FIGS. 4A and 4B in a first variation example of the relation between a second unit section and a third unit section;

FIGS. 10A and 10B are graphs showing the isolation and/or attenuation characteristics of the SAW device of FIGS. 4A and 4B in a second variation example of the relation between the second unit section and the third unit section;

FIGS. 11A and 11B are graphs showing the isolation and/or attenuation characteristics of the SAW device of FIGS. 4A and 4B in a third variation example of the relation between the second unit section and the third unit section; and

FIGS. 12A and 12B are graphs showing the isolation and/or attenuation characteristics of the SAW device of FIGS. 4A and 4B in a first variation example of the relation between the second unit section and the third unit section.

### DETAILED DESCRIPTION OF THE EMBODIMENTS

Hereinafter, example embodiments will be described with reference to the accompanying drawings; however, for reference numerals, with respect to the same elements, even though they may be displayed in different drawings, such elements use same reference numerals as much as possible. Also, in explaining the example embodiments, detailed description on known elements or functions will be omitted if it is determined that such description will interfere with understanding of the embodiments. In the drawing figures, dimensions may be exaggerated for clarity of illustration.

All terms used herein, including technical or scientific terms, unless otherwise defined, have the same meanings which are typically understood by those having ordinary skill in the art. The terms, such as ones defined in common dictionaries, should be interpreted as having the same meanings as terms in the context of pertinent technology, and should not be interpreted as having ideal or excessively formal meanings unless clearly defined in the specification. Terms used in this application are used to only describe specific exemplary embodiments and are not intended to restrict the present invention. An expression referencing a singular value additionally refers to a corresponding expression of the plural number, unless explicitly limited otherwise by the context.

The term ‘comprises’ and/or ‘includes’, as used herein are intended to refer to the above features, numbers, steps, operations, elements, parts or combinations, and it is to be understood that the terms are not intended to preclude the presence of one or more features, numbers, steps, operations, elements, parts or combinations and added possibilities.

### 1. Background of Embodiments of the Present Invention Suggested by the Inventor

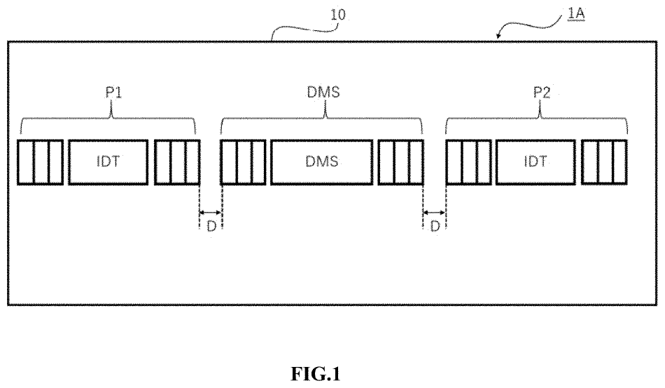

FIG. 1 is a schematic diagram showing a portion of a configuration of an SAW device (duplexer) having an SAW resonator in a conventional practice.

As shown in FIG. 1, an SAW device (duplexer) 1A in the conventional practice includes a double mode SAW (DMS) filter located on a piezoelectric substrate 1, an SAW resonator P1 located serially with the DMS filter on the piezoelectric substrate 1 in such a manner as to be adjacent to one end of the DMS filter, and an SAW resonator P2 located serially with the DMS filter in the piezoelectric substrate 1 in such a manner as to be adjacent to the other end of the DMS filter.

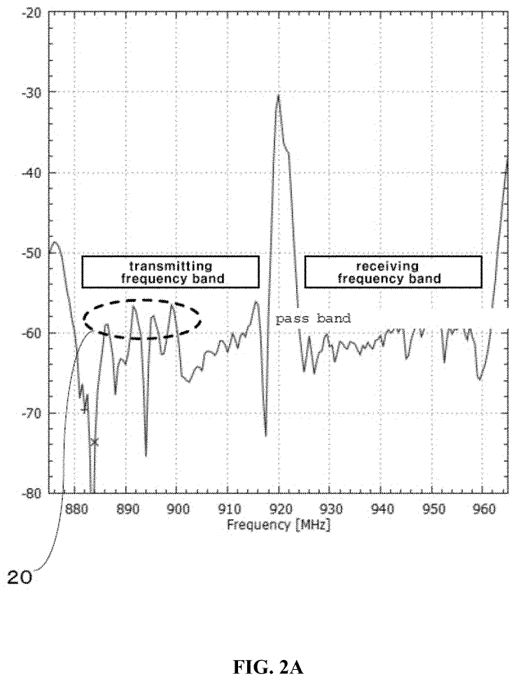

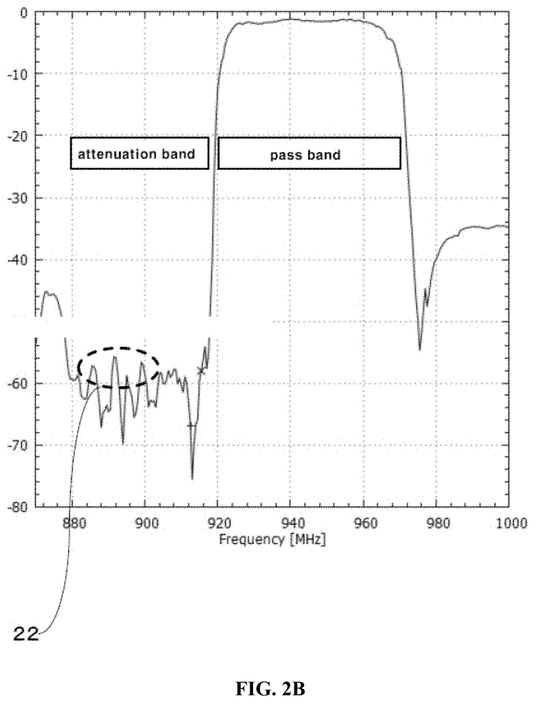

In this configuration, as shown in FIGS. 2A and 2B, the isolation and/or attenuation characteristics of the duplexer 1A may be deteriorated badly due to the spurious signals generated by the acoustic coupling between the SAW resonator P1 and the DMS filter and between the SAW resonator P2 and the DMS filter.

FIGS. 2A and 2B are graphs showing the isolation and attenuation characteristics of the SAW device 1A of FIG. 1. FIG. 2A shows the isolation characteristics of the SAW device 1A indicating an amount of frequency components contained in a signal leaking to an Rx (Receiving) port from a Tx (Transmitting) port, and in this case, the horizontal axis indicates a frequency MHz, while the vertical axis is indicating attenuation dB. A higher frequency band than a guard band around about 920 MHz frequency is used as a receiving frequency band, and a lower frequency band than the guard band as a transmitting frequency band. In the signal leaking to the Rx port from the Tx port, as indicated by a reference numeral 20, some peaks occur in the transmitting frequency band. Like this, the isolation characteristics of the SAW device 1A of FIG. 1 are deteriorated badly.

FIG. 2B shows the attenuation characteristics of the SAW device 1A indicating an amount of frequency components contained in a signal received from an antenna port and transmitted to the Rx port, and in this case, the horizontal axis indicates a frequency MHz, while the vertical axis is indicating attenuation dB. The frequency components of the signal received from the antenna port, which correspond to an attenuation band, are attenuated, and the frequency components corresponding to a pass band are passed. In the signal transmitted to the Rx port, as indicated by a reference numeral 22, some peaks occur in the attenuation band. Like this, the attenuation characteristics of the SAW device of FIG. 1 are deteriorated badly.

So as to solve such problems, accordingly, the DMS filter and the SAW resonator P1 (and the SAW resonator P2) are not located serially with each other. As a result, the SAW leaking from the DMS filter is not received by the respective SAW resonators P1 and P2, and the Surface acoustic wave leaking from the respective SAW resonators P1 and P2 are not received by the DMS filter. However, this solution fails to miniaturize the SAW device 1A.

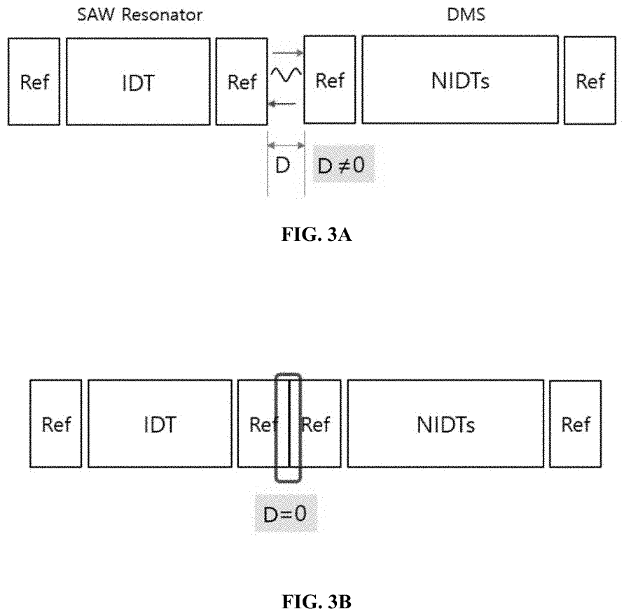

Unlike the conventional SAW device as shown in FIG. 3A in which a distance(D) between a reflector of the DMS filter and a reflector of at least one SAW resonator adjacent to the reflector of the DMS reflector is greater than zero, the inventor suggests an SAW device according to the present invention as shown in FIG. 3B in which a distance(D) between a reflector of a DMS filter and a reflector of at least one SAW resonator adjacent to the reflector of the DMS reflector is zero 0, thereby providing embodiments of the present invention capable of improving the isolation and/or attenuation characteristics of the Surface acoustic wave in the SAW device.

### 2. Embodiments of the Present Invention

### 2-1. The Whole Configuration of the SAW Device 100

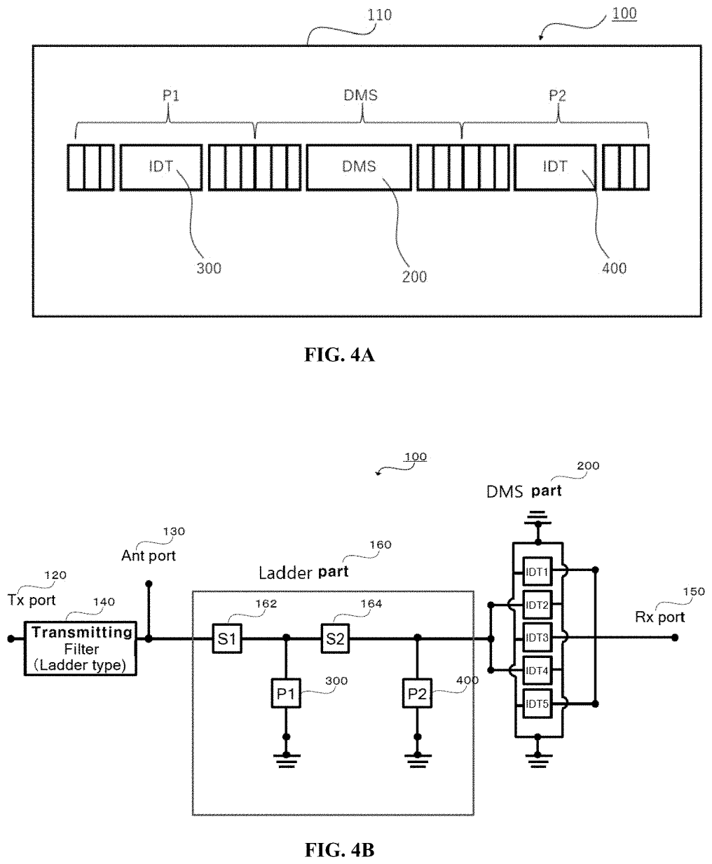

FIG. 4A is a top view showing a portion of a configuration of an SAW device (duplexer) according to an embodiment of the present invention. FIG. 4B is a schematic circuit diagram showing a portion of the configuration of the SAW device of FIG. 4A.

As shown in FIG. 4A, an SAW device (duplexer) 100 according to an embodiment of the present invention includes a double mode SAW (DMS) filter 200 located on a piezoelectric substrate 110, an SAW resonator 300 located serially with the DMS filter on the piezoelectric substrate 110 in such a manner as to be adjacent to one end of the DMS filter 200, and an SAW resonator 400 located serially with the DMS filter 200 in the piezoelectric substrate 110 in such a manner as to be adjacent to the other end of the DMS filter 200.

For example, the piezoelectric substrate 110 is made of a given piezoelectric material like LT (LiTaO₃) or LN (LiNbO₃).

In FIG. 4A, further, the SAW resonator 300 and the SAW resonator 400 are adjacent to both ends of the DMS filter 200, but of course, the SAW resonator 300 or 400 may be adjacent only to any end of the DMS filter 200.

In FIG. 4B, the SAW device (duplexer) 100 according to the embodiment of the present invention largely includes a transmitting filter 140 located between a Tx port 120 and an antenna port 130 and a ladder part 160 and the DMS filter 200 that are located between the antenna port 130 and an Rx port 150.

The transmitting filter 140 is a band-pass filter that serves to pass the frequency components of the transmitting signal received from the Tx port 120 that correspond to a pass band therethrough and to attenuate the frequency components of the transmitting signal received from the Tx port 120 that correspond to an attenuation band. The transmitting signal outputted from the transmitting filter 140 is transmitted through the antenna port 130.

The ladder part 160 includes a first serial arm SAW resonator 162 and a second serial arm SAW resonator 164 that are located between the antenna port 130 and the DMS filter 200. Further, the ladder part 160 includes a first parallel arm SAW resonator 300 connected between a signal line (connecting the first serial arm SAW resonator 162 and the second serial arm SAW resonator 164) and ground and a second parallel arm SAW resonator 400 connected between a signal line (connecting the second serial arm SAW resonator 164 and the DMS filter 200) and ground.

Each of the first serial arm SAW resonator 162, the second serial arm SAW resonator 164, the first parallel arm SAW resonator 300, and the second parallel arm SAW resonator 400 includes a reflector (not shown) and a plurality of comb-shaped electrodes (not shown), that is, interdigital transducers (IDTs) (not shown) adjacent to the reflector.

The DMS filter 200 includes a plurality of comb-shaped electrodes (IDTs), for example, five IDTs (in this case, the total number of IDTs is not limited). On the other hand, the DMS filter 200 may have at least one reflector (not shown) located adjacent to the plurality of IDTs.

The first parallel arm SAW resonator 300 as shown in FIG. 4B is located adjacent to one end of the DMS filter 200 on the piezoelectric substrate 110, as mentioned with reference to FIG. 4A. In the same manner as above, the second parallel arm SAW resonator 400 as shown in FIG. 4B is located adjacent to the other end of the DMS filter 200 on the piezoelectric substrate 110, as mentioned with reference to FIG. 4A.

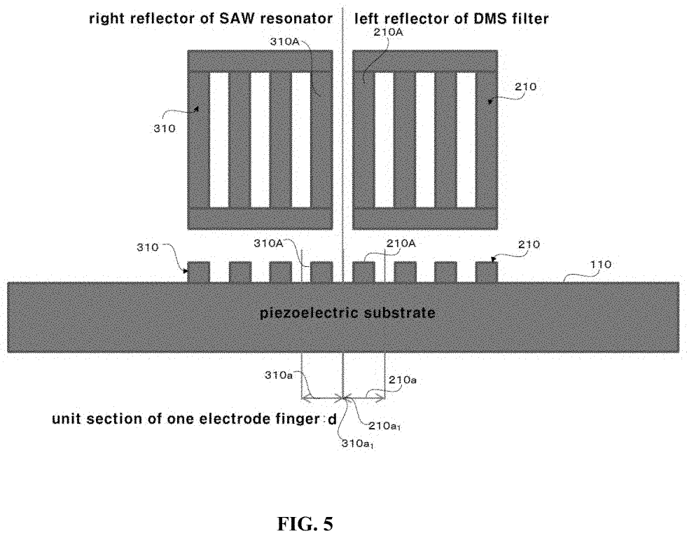

A position relation between the first parallel arm SAW resonator 300 and the DMS filter 200 will be explained with reference to FIG. 5. FIG. 5 shows a position relation between the DMS filter 200 of FIGS. 4A and 4B and the first parallel arm SAW resonator 300.

On the upper end of FIG. 5, top views showing a reflector (a first reflector) 210 of the DMS filter 200 and a reflector (a second reflector) 310 of the first parallel arm SAW resonator 300 are provided. On the lower end of FIG. 5, sectional views showing the first reflector 210 and the second reflector 310 are provided.

Each of the first reflector 210 and the second reflector 310 has a plurality of electrode fingers (four electrode fingers in an extremely simplified example) located in almost parallel to one another.

A distance (D) between the first reflector 210 and the second reflector 310 is zero. In specific, the first reflector 210 and the second reflector 310 are located in such a manner as to allow an end portion 210a₁ of a unit section 210a of the outermost electrode finger 210A of the plurality of electrode fingers of the first reflector 210 to correspond to or come into contact with an end portion 310a₁ of a unit section 310a of the outermost electrode finger 310A of the plurality of electrode fingers of the second reflector 310.

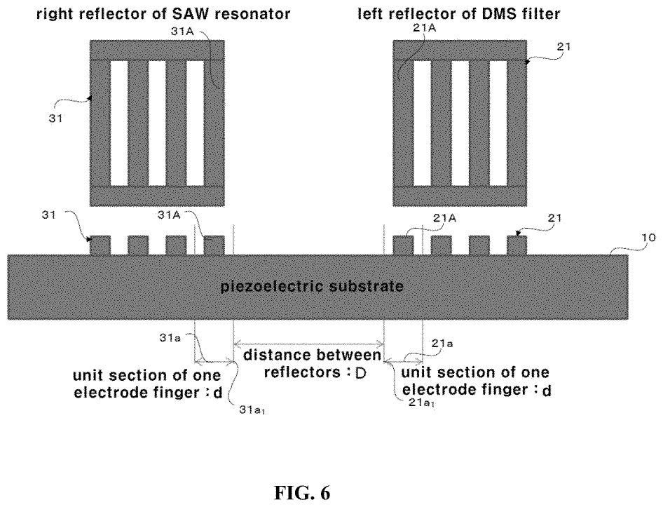

Also, FIG. 6 shows the configuration of the SAW device 1A in the conventional practice when compared with the configuration of FIG. 5. FIG. 6 shows a position relation between the DMS filter and the SAW resonator P1 as shown in FIG. 1.

On the upper end of FIG. 6, top views showing a reflector 21 of the DMS filter and a reflector 31 of the SAW resonator P1 are provided. On the lower end of FIG. 6, sectional views showing the reflector 21 and the reflector 31 are provided.

A distance(D) between the first reflector 21 and the second reflector 31 is greater than zero. In specific, an end portion 21a₁ of a unit section 21a of the outermost electrode finger 21A of the plurality of electrode fingers of the reflector 21 does not correspond to an end portion 31a₁ of a unit section 31a of the outermost electrode finger 31A of the plurality of electrode fingers of the reflector 31. That is, there is a given distance between the end portion 21a₁ of the unit section 21a of the outermost electrode finger 21A and the end portion 31a₁ of the unit section 31a of the outermost electrode finger 31A.

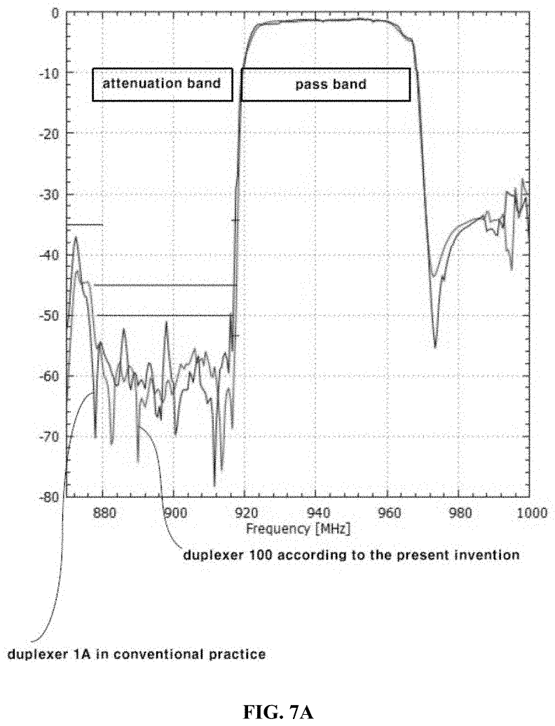

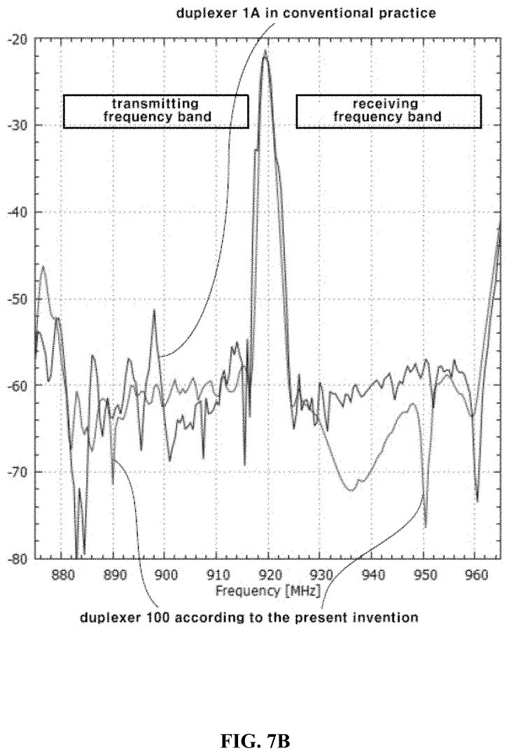

FIGS. 7A and 7B are graphs showing the comparison of the isolation and attenuation characteristics between the SAW device of FIGS. 4A and 4B and the SAW device of FIG. 1.

FIG. 7A shows the attenuation characteristics indicating an amount of frequency components contained in a signal received from the antenna port 130 and transmitted to the Rx port 150, and in this case, the horizontal axis indicates frequencies MHz, while the vertical axis is indicating attenuation dB. The frequency components of the signal received from the antenna port 130, which correspond to an attenuation band, are attenuated, and the frequency components of the signal received from the antenna port 130, which correspond to a pass band, are passed. In the signal transmitted to the Rx port 150, it will be understood that an amount of attenuation in the attenuation band is more increased when compared to the SAW duplexer 1A in the conventional practice.

FIG. 7B shows the isolation characteristics indicating an amount of frequency components contained in a signal leaking from the Tx port 120 to the Rx port 150, and in this case, the horizontal axis indicates frequencies MHz, while the vertical axis is indicating attenuation dB. A higher frequency band than a guard band around about 920 MHz frequency is used as a receiving frequency band, and a lower frequency band than the guard band as a transmitting frequency band. In the signal leaking to the Rx port 150 from the Tx port 120, it will be understood that an amount of attenuation in the transmitting frequency band is more increased when compared to the SAW duplexer 1A in the conventional practice.

As mentioned above, the example in which the distance between the first reflector 210 (facing the SAW resonator 300) of the DMS filter 200 and the second reflector 310 (facing the DMS filter 200) of the SAW resonator 300 is zero has been explained with reference to FIGS. 5, 7A and 7B. However, of course, a distance between a third reflector (not shown and facing the SAW resonator 400 in FIG. 4A) of the DMS filter 200 and a fourth reflector (not shown and facing the DMS filter 200) of the SAW resonator 400 may be zero. In this case, the third reflector and the fourth reflector are located in such a manner as to allow an end portion of a unit section of the outermost electrode finger of a plurality of electrode fingers of the third reflector to correspond to an end portion of a unit section of the outermost electrode finger of a plurality of electrode fingers of the fourth reflector.

### 2-2. Desirable Example of the First Reflector 210 and the Second Reflector 310

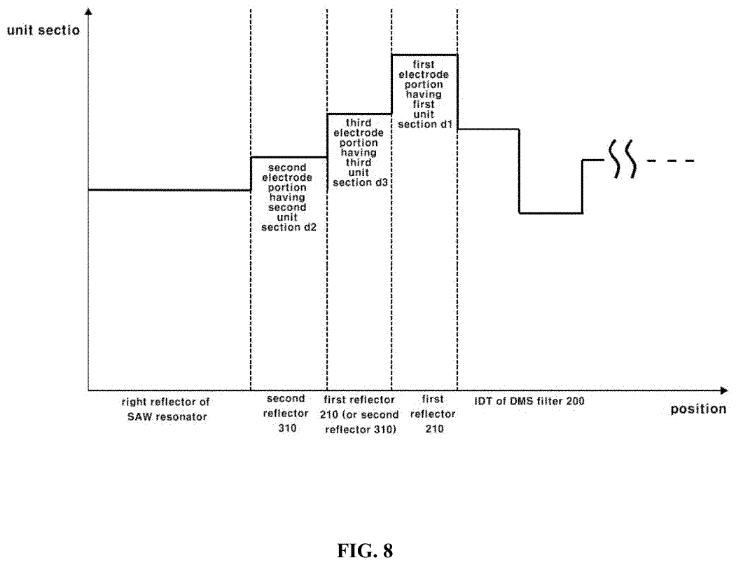

So as to effectively improve the isolation and/or attenuation characteristics of the SAW device 100, next, the length setting of the unit sections of the first reflector 210 and the second reflector 310 will be explained with reference to FIG. 8.

FIG. 8 is a schematic diagram showing examples of unit section lengths of the electrode fingers of the DMS filter 200, the first reflector 210, the second reflector 310, and the SAW resonator 300 of FIGS. 4A and 4B. In FIG. 8, the horizontal axis indicates a longitudinal position on the piezoelectric substrate 110, and the vertical axis indicates a unit section length.

According to the present invention, as shown in FIG. 8, the first reflector 210 includes a first electrode portion set to allow each electrode finger to have a first unit section d₁. According to the present invention, the first unit section d₁ is larger than the unit section of the plurality of comb-shaped electrodes of the DMS filter 200.

Further, the first reflector 210 may have a third electrode portion adjacent to the first electrode portion toward the second reflector 310. The third electrode portion is set to allow each electrode finger to have a third unit section d₃.

Also, the second reflector 310 includes a second electrode portion set to allow each electrode finger to have a second unit section d₂. According to the present invention, the second unit section d₂ is smaller than the third unit section d₃ and is larger than the unit section of the plurality of comb-shaped electrodes of the SAW resonator 300.

The first electrode portion serves to reflect a surface acoustic wave emitted from the plurality of comb-shaped electrodes of the DMS filter 200 towards the DMS filter 200, and the second electrode portion serves to reflect the surface acoustic wave emitted from the plurality of comb-shaped electrodes of the SAW resonator 300 towards the SAW resonator 300.

The third electrode portion serves to offset the surface acoustic wave emitted from the plurality of comb-shaped electrodes of the DMS filter 200 with the surface acoustic wave emitted from the plurality of comb-shaped electrodes of the SAW resonator 300. The function can suppress the spurious signals generated by the acoustic coupling between the DMS filter 200 and the SAW resonator 300, thereby improving the isolation and/or attenuation characteristics of the SAW device 100.

Further, the second unit section d₂ and the third unit section d₃ are set to satisfy the following relation equation (1).

1.04≥d₃/d₂≥1.03 (1)

On the other hand, in FIG. 8, the third electrode portion is included in the first reflector 210. According to another embodiment of the present invention, however, the third electrode portion may be included in the second reflector 310.

Further, the first reflector 210 has the first electrode portion and the third electrode portion adjacent to the first electrode portion, which means that the unit section of each electrode finger is the first unit section d₁ in the first electrode portion and is the third unit section d₃ in the third electrode portion. According to another embodiment of the present invention, the second reflector 310 has the third electrode portion and the second electrode portion adjacent to the third electrode portion, which means that the unit section of each electrode finger is the third unit section d₃ in the third electrode portion and is the second unit section d₂ in the second electrode portion.

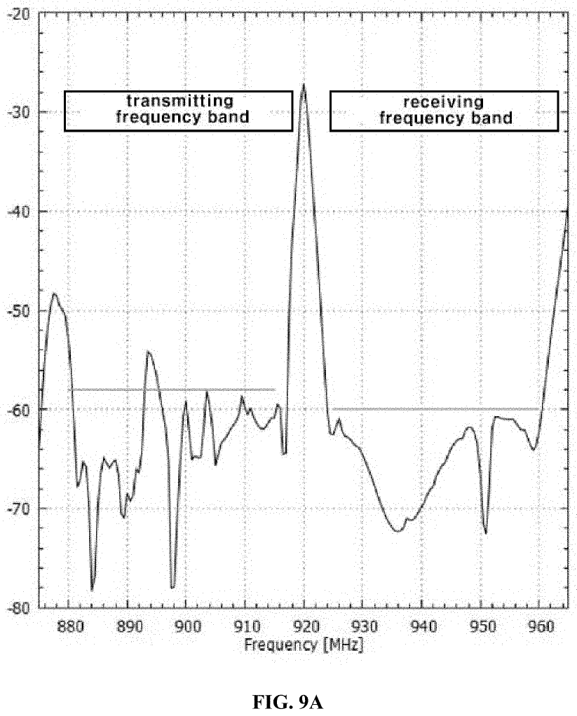

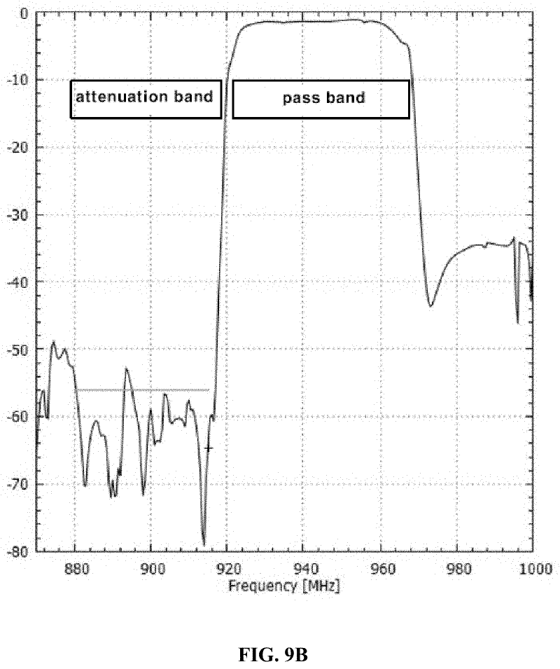

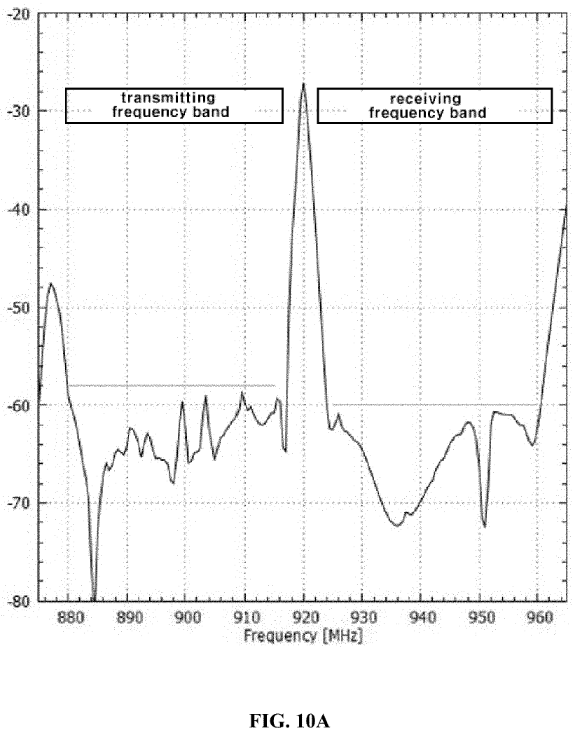

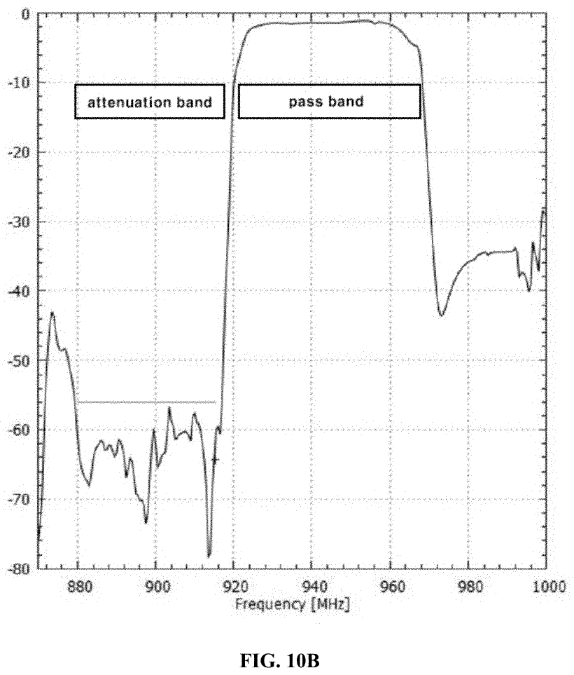

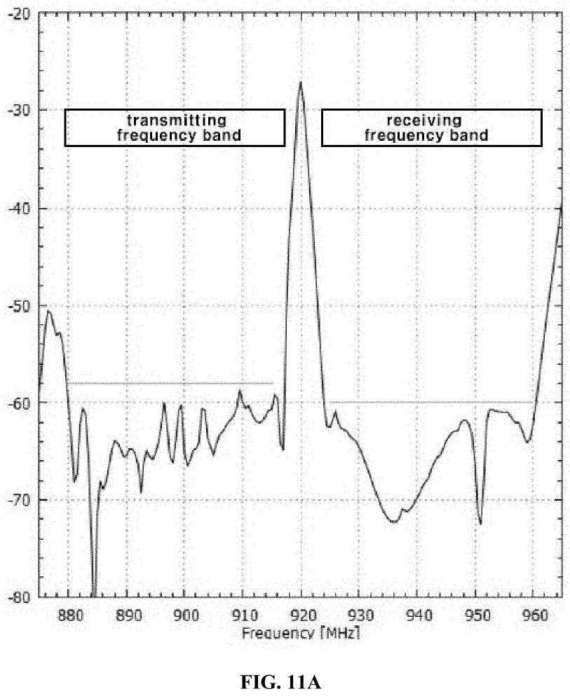

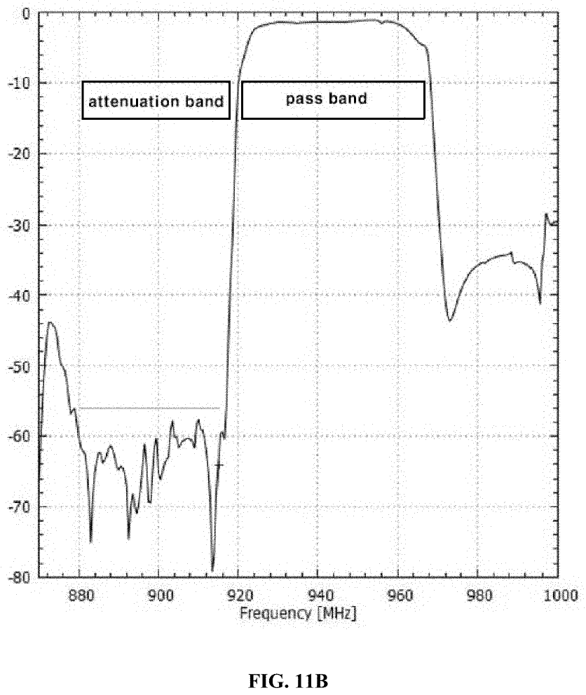

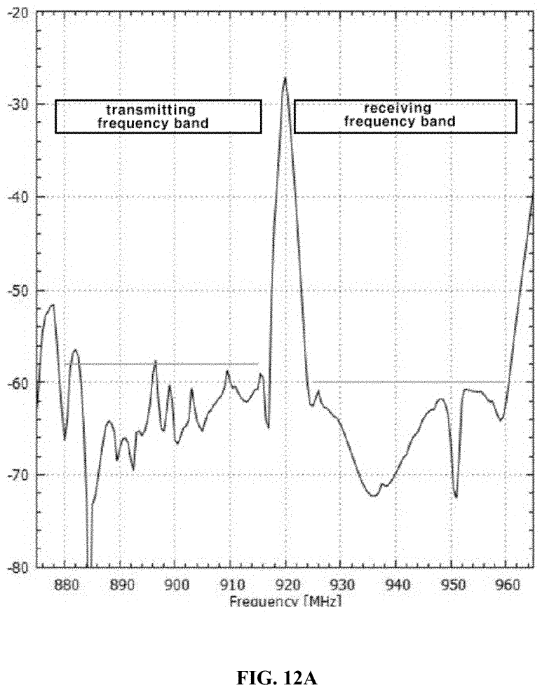

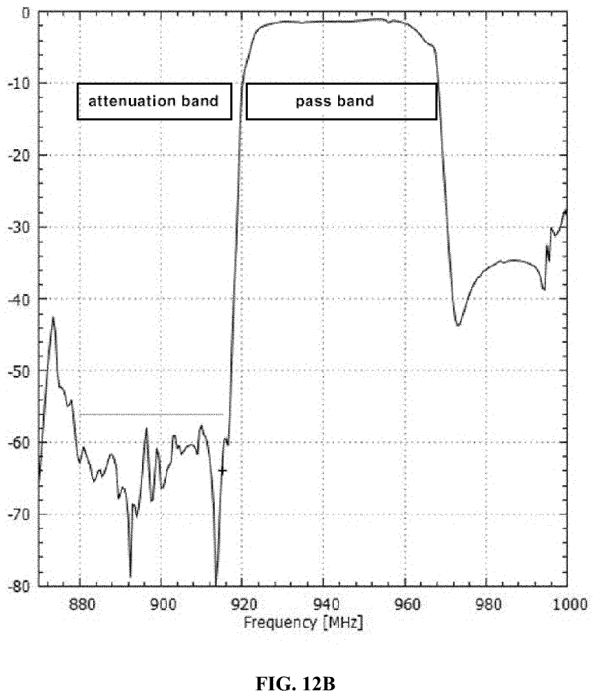

Next, experimental results for the equation (1) will be explained with reference to FIGS. 9A to 12B. FIGS. 9A and 9B are graphs showing the isolation and/or attenuation characteristics of the SAW device of FIGS. 4A and 4B in a first variation example of the relation between the second unit section d₂ and the third unit section d₃. FIGS. 10A and 10B are graphs showing the isolation and/or attenuation characteristics of the SAW device of FIGS. 4A and 4B in a second variation example of the relation between the second unit section d₂ and the third unit section d₃. FIGS. 11A and 11B are graphs showing the isolation and/or attenuation characteristics of the SAW device of FIGS. 4A and 4B in a third variation example of the relation between the second unit section d₂ and the third unit section d₃. FIGS. 12A and 12B are graphs showing the isolation and/or attenuation characteristics of the SAW device of FIGS. 4A and 4B in a first variation example of the relation between the second unit section d₂ and the third unit section d₃.

On the other hand, as shown in FIGS. 9A to 12B, left side graphs show the isolation characteristics of the SAW device 100, and the right side graphs show the attenuation characteristics of the SAW device 100. A method for analyzing the isolation and/or attenuation characteristics is the same as in FIGS. 2A, 2B, 7A, and 7B, and accordingly, an explanation of the method will be avoided.

In the case of d₃/d₂=1.02, as shown in FIGS. 9A and 9B, that is, in the case where the equation (1) is not satisfied, the isolation and/or attenuation characteristics of the SAW device 100 are provided. Referring to FIG. 9A showing the isolation characteristics of the SAW device 100, peaks, which do not satisfy a target value of 58 dB (which is arbitrarily set, as just one example), occur in the transmitting frequency band of the signal outputted from the Rx port 150. Referring to FIG. 9B showing the attenuation characteristics of the SAW device 100, peaks, which do not satisfy a target value of 56 dB (which is arbitrarily set, as just one example), occur in the attenuation band of the signal outputted from the Rx port 150.

In the case of d₃/d₂=1.03, as shown in FIGS. 10A and 10B, that is, in the case where the equation (1) is satisfied, the isolation and/or attenuation characteristics of the SAW device 100 are provided. Referring to FIG. 10A showing the isolation characteristics of the SAW device 100, peaks, which do not satisfy the target value of 58 dB (which is arbitrarily set, as just one example), do not occur in the transmitting frequency band of the signal outputted from the Rx port 150. Referring to FIG. 10B showing the attenuation characteristics of the SAW device 100, peaks, which do not satisfy the target value of 56 dB (which is arbitrarily set, as just one example), do not occur in the attenuation band of the signal outputted from the Rx port 150.

In the case of d₃/d₂=1.04, as shown in FIGS. 11A and 11B, that is, in the case where the equation (1) is satisfied, the isolation and/or attenuation characteristics of the SAW device 100 are provided. Referring to FIG. 11A showing the isolation characteristics of the SAW device 100, peaks, which do not satisfy the target value of 58 dB (which is arbitrarily set, as just one example), do not occur in the transmitting frequency band of the signal outputted from the Rx port 150. Referring to FIG. 11B showing the attenuation characteristics of the SAW device 100, peaks, which do not satisfy the target value of 56 dB (which is arbitrarily set, as just one example), do not occur in the attenuation band of the signal outputted from the Rx port 150.

In the case of d₃/d₂=1.05, as shown in FIGS. 12A and 12B, that is, in the case where the equation (1) is not satisfied, the isolation and/or attenuation characteristics of the SAW device 100 are provided. Referring to FIG. 12A showing the isolation characteristics of the SAW device 100, peaks, which do not satisfy the target value of 58 dB (which is arbitrarily set, as just one example), occur in the transmitting frequency band of the signal outputted from the Rx port 150. Referring to FIG. 12B showing the attenuation characteristics of the SAW device 100, peaks, which do not satisfy the target value of 56 dB (which is arbitrarily set, as just one example), occur in the attenuation band of the signal outputted from the Rx port 150.

According to the experimental results as shown in FIGS. 9A to 12B, more desirably, setting the second unit section d₂ and the third unit section d₃ to satisfy the equation (1) enables the isolation and/or attenuation characteristics of the SAW device 100 to be effectively improved. Further, the embodiments of the present invention do not exclude an SAW device in which the second unit section d₂ and the third unit section d₃ are set to the range that does not satisfy the equation (1), and in this case, the SAW device may be applied to a low-end specification.

### 3. Modifications

According to the embodiments of the present invention, on the other hand, the present invention relates to the duplexer as the SAW device, but of course, the present invention may relate to a receiving filter circuit (for example, that is the configuration as shown in FIG. 4B from which the transmitting filter 140 is removed).

According to the embodiments of the present invention, also, the parallel arm SAW resonators are located adjacent to one end or both ends of the DMS filter 200, but of course, one of the serial arm SAW resonator and the parallel arm SAW resonator may be located adjacent to one end or both ends of the DMS filter 200.

Further, the present invention is applicable to a configuration in which the SAW resonators are located adjacent to one end or both ends of the DMS filter 200, without any limitations in the number of SAW resonators of the ladder part 160, the total number of comb-shaped electrodes (IDTs) of the DMS filter 200, and the total number of comb-shaped electrodes (IDTs) of each SAW resonator.

According to the embodiments of the present invention, furthermore, the DMS filter 200, the SAW resonator 300, and/or the SAW resonator 400 are located serially with one another in a line, but of course, the present invention may be not limited thereto. In specific, the present invention may be applied to all of configurations where the SAW resonator 300 and/or the SAW resonator 400 are located on positions laid on at least a portion of a transmission path of a surface acoustic wave generated from the DMS filter 200. For example, only if the SAW resonator 300 and/or the SAW resonator 400 are located on the positions laid on at least a portion of a transmission path of a surface acoustic wave generated from the DMS filter 200, they may be arranged to cross each other in upward and downward directions with respect to the DMS filter 200 as shown in FIG. 4A.

As described above, the SAW device according to the desirable embodiment of the present invention is configured to allow the distance between the reflector of the DMS filter and the reflector of at least one SAW resonator located adjacent to the reflector of the DMS filter to be zero, thereby improving the isolation and/or attenuation characteristics of the surface acoustic wave.

Further, the SAW device according to the more desirable embodiment of the present invention is configured to allow the second unit section d₂ and the third unit section d₃ to be set to satisfy the equation 1.04≥d₃/d₂≥1.03, thereby improving the isolation and/or attenuation characteristics of the surface acoustic wave.

Like this, the present invention can provide the receiving filter circuit and the duplexer that are capable of being improved in their performance.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A receiving filter circuit comprising:
a double mode surface acoustic wave (DMS) filter placed on a piezoelectric substrate and having a first reflector and a plurality of comb-shaped electrodes located adjacent to the first reflector; and
a surface acoustic wave (SAW) resonator placed on the piezoelectric substrate in such a manner as to be laid on at least a portion of a transmission path of a surface acoustic wave generated from the DMS filter and having a second reflector located on a position with a distance of zero from the first reflector and a plurality of comb-shaped electrodes located adjacent to the second reflector.

2. The receiving filter circuit according to claim 1, wherein the first reflector comprises a first electrode portion in which one electrode finger has a first unit section (dᵢ), the second reflector comprises a second electrode portion in which one electrode finger has a second unit section (d₂), the first reflector or the second reflector comprising a third electrode portion in which one electrode finger has a third unit section (d₃) in such a manner as to be located between the first electrode portion and the second electrode portion, and the second unit section (d₂) and the third unit section (d₃) are set to satisfy a relation equation 1.04≥d₃/d₂≥1.03.

3. The receiving filter circuit according to claim 1, wherein the first reflector and the second reflector are located in such a manner as to allow an end portion of a unit section of the outermost electrode finger of the first reflector to correspond to an end portion of a unit section of the outermost electrode finger of the second reflector.

4. The receiving filter circuit according to claim 3, wherein the first unit section (d₁) is greater than the third unit section (d₃).

5. The receiving filter circuit according to claim 4, wherein the first electrode portion serves to reflect a surface acoustic wave emitted from the plurality of comb-shaped electrodes of the DMS filter towards the DMS filter, the second electrode portion serves to reflect a surface acoustic wave emitted from the plurality of comb-shaped electrodes of the SAW resonator towards the SAW resonator, and the third electrode portion serves to offset the surface acoustic wave emitted from the plurality of comb-shaped electrodes of the DMS filter with the surface acoustic wave emitted from the plurality of comb-shaped electrodes of the SAW resonator.
